(19) United States
(12) Patent Application Publication
(10) Pub. No.: US 2025/0279311 A1
(43) Pub. Date: Sep. 4, 2025

(54) SUBSTRATE FIXING DEVICE

(71) Applicant: SHINKO ELECTRIC INDUSTRIES CO., LTD., Nagano-shi (JP)

(72) Inventors: Keita Sato, Nagano (JP); Riku Nishikawa, Nagano (JP)

(21) Appl. No.: 19/068,326

(22) Filed: Mar. 3, 2025

(30) Foreign Application Priority Data
Mar. 4, 2024 (JP) 2024-032253

(51) Int. Cl. H01L 21/683; H01J 37/32

(52) U.S. Cl. CPC H01L 21/6833; H01J 37/32715; H01J 2237/2007

(57) ABSTRACT

A substrate fixing device includes a ceramic base plate, a ceramic electrostatic chuck having a mounting surface on which an object to be sucked is mounted, and a first brazing part joining the base plate and the electrostatic chuck. The base plate is made of a ceramic material having a thermal expansion coefficient of 0±3 ppm/K at a room temperature. The electrostatic chuck is made of a ceramic material having a thermal expansion coefficient of 0±3 ppm/K at the room temperature.

### TECHNICAL FIELD

The present invention relates to a substrate fixing device.

### BACKGROUND ART

In the related art, a film forming device (for example, a chemical vapor deposition (CVD) device or a physical vapor deposition (PVD) device) or a plasma etching device used for manufacturing a semiconductor element such as an IC or an LSI has a substrate fixing device for accurately holding a substrate such as a silicon wafer in a vacuum processing chamber. In a substrate fixing device, a ceramic electrostatic chuck is bonded onto a metal base plate by an adhesive layer (for example, see JP2020-23088A).

### SUMMARY OF INVENTION

In the substrate fixing device of the related art, a temperature of a mounting surface of the electrostatic chuck on which an object to be sucked is mounted may vary. Specifically, when the substrate fixing device is exposed to a low temperature of about −60° C. or a high temperature of about 180° C., a large difference occurs between a thermal deformation amount of the electrostatic chuck and a thermal deformation amount of the base plate.

When a large stress acts on the adhesive layer, cohesive failure may occur in the adhesive layer. When cohesive failure occurs in the adhesive layer, in-plane uniformity of a thermal resistance of the adhesive layer is reduced, so that the temperature of the mounting surface of the electrostatic chuck varies.

According to one aspect of the present disclosure, there is provided a substrate fixing device includes a ceramic base plate, a ceramic electrostatic chuck having a mounting surface on which an object to be sucked is mounted, and a first brazing part joining the base plate and the electrostatic chuck. The base plate is made of a ceramic material having a thermal expansion coefficient of 0±3 ppm/K at a room temperature. The electrostatic chuck is made of a ceramic material having a thermal expansion coefficient of 0±3 ppm/K at the room temperature.

According to one aspect of the present disclosure, it is possible to improve the uniformity of the temperature of the mounting surface.

### BRIEF DESCRIPTION OF DRAWINGS

FIG. 1 is a schematic cross-sectional view showing a substrate fixing device according to an embodiment.

FIG. 2 is an enlarged cross-sectional view showing a part of the substrate fixing device shown in FIG. 1.

FIG. 3 is a schematic cross-sectional view showing a manufacturing method for the substrate fixing device.

FIG. 4 is a schematic cross-sectional view showing the manufacturing method for the substrate fixing device.

FIG. 5 is a schematic cross-sectional view showing the manufacturing method for the substrate fixing device.

FIG. 6 is a schematic cross-sectional view showing a substrate fixing device according to a modification.

### DESCRIPTION OF EMBODIMENTS

Hereinafter, an embodiment will be described with reference to the accompanying drawings.

In addition, in the accompanying drawings, for the sake of convenience, a portion serving as characteristics may be shown in an enlarged manner in order to facilitate understanding of the characteristics, and a dimensional ratio of each component may be different in each drawing. In the cross-sectional view, hatching of some members is shown instead of a satin-like pattern in order to facilitate understanding of a cross-sectional structure of each member, and hatching of some members is omitted. In this specification, an “upper-lower direction” and a “left-right direction” are directions in a case where a direction in which a sign indicating each member is correctly read in each drawing is a positive position.

### Overall Configuration of Substrate Fixing Device 10

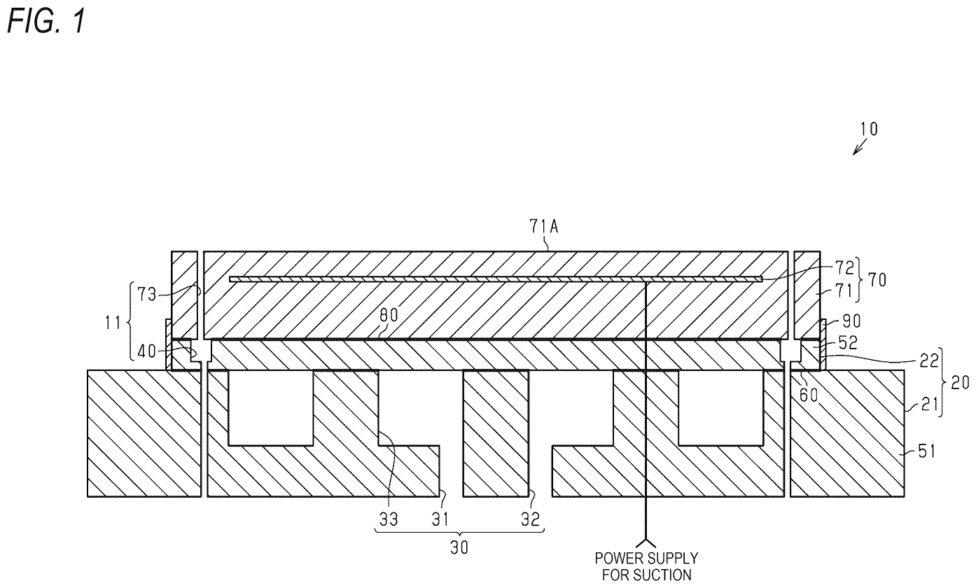

As shown in FIG. 1, the substrate fixing device 10 includes a ceramic base plate 20, a ceramic electrostatic chuck 70, and a brazing part 80 joining the base plate 20 and the electrostatic chuck 70. The substrate fixing device 10 includes, for example, a protective layer 90 that protects the brazing part 80. The electrostatic chuck 70 is fixed to an upper surface of the base plate 20 by the brazing part 80. The substrate fixing device 10 is a device that sucks and holds a substrate (not shown) that is an object to be sucked by the electrostatic chuck 70 mounted on the upper surface of the base plate 20. Examples of the substrate include a silicon wafer. A diameter of the substrate may be, for example, about 8 inches, 12 inches, or 18 inches.

A low thermal expansion ceramic material having a low thermal expansion coefficient can be used as materials of the base plate 20 and the electrostatic chuck 70. As the low thermal expansion ceramic material, for example, a ceramic material having a thermal expansion coefficient of 0±3 ppm/K at a room temperature can be used. If the thermal expansion coefficient is 0±3 ppm/K, cohesive failure of the adhesive layer can be prevented. In addition, as a low thermal expansion ceramic material, it is more preferable to use a ceramic material having a thermal expansion coefficient of 0±1 ppm/K at the room temperature. That is, a ceramic material having a thermal expansion coefficient of zero can be used as the low thermal expansion ceramic material. As the low thermal expansion ceramic material, for example, a ceramic material having cordierite (2MgO·2Al₂O₃·5SiO₂) as a main component can be used. Here, the “main component” in the specification refers to a component that occupies 90% by weight or more of the components contained in a target site. The material of the base plate 20 and the material of the electrostatic chuck 70 may be the same ceramic material or different ceramic materials. The room temperature is a temperature range of about 22° C. to 26° C.

### Configuration of Base Plate 20

The base plate 20 is a base (base) on which the electrostatic chuck 70 is mounted. The base plate 20 has rigidity for supporting the electrostatic chuck 70. A thickness of the base plate 20 can be, for example, approximately 20 mm to 50 mm.

The base plate 20 includes a lower portion 21 and an upper portion 22 laminated on an upper surface of the lower portion 21. The lower portion 21 is formed in a disk shape, for example. The upper portion 22 is formed in a disk shape, for example. For example, the upper portion 22 is concentrically disposed on the upper surface of the lower portion 21. A planar size of the upper portion 22 is smaller than a planar size of the lower portion 21. It should be noted that a “planar size” in this specification is a size in a direction perpendicular to a laminating direction of the base plate 20, the brazing part 80, and the electrostatic chuck 70, that is, in the left-right direction. A diameter of the upper portion 22 is smaller than a diameter of the lower portion 21. The upper portion 22 protrudes upward from the upper surface of the lower portion 21.

A cooling path 30 is provided inside the base plate 20, for example. The cooling path 30 includes an introduction portion 31 provided at one end thereof and a discharge portion 32 provided at the other end thereof. The cooling path 30 is, for example, connected to a cooling medium control device (not shown) provided outside the substrate fixing device 10. The cooling medium control device introduces the cooling medium from the introduction portion 31 to the cooling path 30 and discharges the cooling medium from the discharge portion 32. By circulating a cooling medium through the cooling path 30 to cool the base plate 20, the substrate sucked to the electrostatic chuck 70 can be cooled. For example, water or Galden may be used as the cooling medium.

A gas flow path 40, for example, is provided inside the base plate 20. The gas flow path 40 penetrates the base plate 20 in a thickness direction (an upper-lower direction in the drawing). Specifically, the gas flow path 40 penetrates from the upper surface of the upper portion 22 to a lower surface of the lower portion 21. For example, a gas for cooling the substrate sucked on the electrostatic chuck 70 is introduced into the gas flow path 40. An inert gas may be used as gas for cooling. Examples of the inert gas include helium (He) gas and argon (Ar) gas.

The base plate 20 has, for example, a structure in which a plurality of (here, two layers) ceramic plates 51 and 52 are laminated. The base plate 20 includes the ceramic plates 51 and 52 and a brazing part 60 joining the ceramic plates 51 and 52. The ceramic plate 52 is joined to the upper surface of the ceramic plate 51 by the brazing part 60.

The ceramic plate 51 constitutes the lower portion 21 of the base plate 20, for example. The ceramic plate 51 is formed in a disk shape, for example. The ceramic plate 51 includes, for example, the introduction portion 31, the discharge portion 32, and recessed portions 33 that constitute the cooling path 30.

The recessed portion 33 is formed to be recessed downward from the upper surface of the ceramic plate 51. The recessed portion 33 is formed to open upward in the ceramic plate 51. The introduction portion 31 is formed to be recessed upward from the lower surface of the ceramic plate 51 and to communicate with the recessed portion 33. The introduction portion 31 is formed to open downward in the ceramic plate 51. The discharge portion 32 is formed to be recessed upward from the lower surface of the ceramic plate 51 and to communicate with the recessed portion 33. The discharge portion 32 is formed to open downward in the ceramic plate 51.

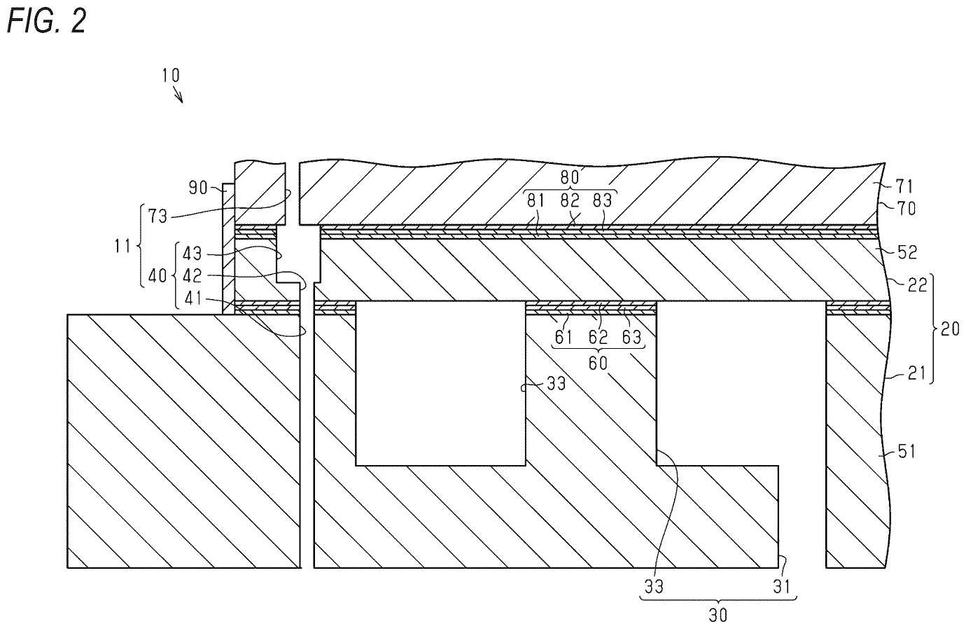

As shown in FIG. 2, the ceramic plate 51 has a hole portion 41 constituting the gas flow path 40. The hole portion 41 penetrates the ceramic plate 51 in the thickness direction. The hole portion 41 is formed to open upward in the ceramic plate 51 and also to open downward in the ceramic plate 51. The hole portion 41 is formed to extend linearly along the thickness direction of the ceramic plate 51, for example.

The ceramic plate 52 constitutes, for example, the upper portion 22 of the base plate 20. The ceramic plate 52 is formed in a disk shape, for example. A planar size of the ceramic plate 52 is smaller than a planar size of the ceramic plate 51.

The ceramic plate 52 is provided to close an opening of the recessed portion 33 of the ceramic plate 51. Thus, the cooling path 30 is formed by the ceramic plate 52 that closes the opening of the recessed portion 33, the recessed portion 33, the introduction portion 31, and the 5 discharge portion 32 (see FIG. 1).

The ceramic plate 52 has hole portions 42 and 43 constituting the gas flow path 40. The hole portion 42 and the hole portion 43 communicate with each other. The hole portion 42 and the hole portion 43 are formed to penetrate the ceramic plate 52 in the thickness direction in cooperation with each other. The hole portion 42 is formed to be recessed upward from a lower surface of the ceramic plate 52. The hole portion 42 is formed to open downward in the ceramic plate 52. The hole portion 42 communicates with the hole portion 41 of the ceramic plate 51. The hole portion 42 is formed to extend linearly along the thickness direction of the ceramic plate 52, for example.

The hole portion 43 is formed to be recessed downward from the upper surface of the ceramic plate 52, and is formed to communicate with the hole portion 42. The hole portion 43 is formed to open upward in the ceramic plate 52. A planar size of the hole portion 43 is, for example, larger than a planar size of the hole portion 42. That is, an opening area of the hole portion 43 is larger than an opening area of the hole portion 42. The hole portion 43 is provided so as to overlap the entire hole portion 42 in a planar view. Further, the ceramic plate 52 may be provided with a groove portion formed to be recessed downward from the upper surface of the ceramic plate 52.

The brazing part 60 includes a conductive pattern 61 formed on the upper surface of the ceramic plate 51, a conductive pattern 62 formed on the lower surface of the ceramic plate 52, and a brazing member 63 joining the conductive patterns 61 and 62.

For example, the conductive pattern 61 is provided so as to overlap the ceramic plate 52 in a planar view. For example, the conductive pattern 61 is provided so as not to overlap the recessed portion 33 and the hole portion 41 in a planar view. For example, the conductive pattern 62 is provided so as to overlap the conductive pattern 61 in a planar view. For example, the conductive pattern 62 is provided so as not to overlap the recessed portion 33 and the hole portions 41 and 42 in a planar view.

The brazing member 63 joins the conductive pattern 61 and the conductive pattern 62. The brazing member 63 is joined to an upper surface of the conductive pattern 61 and also joined to a lower surface of the conductive pattern 62. Thus, the conductive pattern 61 and the conductive pattern 62 are joined to each other by the brazing using the brazing member 63. The ceramic plate 51 and the ceramic plate 52 are joined to each other by joining the conductive pattern 61 and the conductive pattern 62 to each other. Thus, the ceramic plate 52 is laminated on the upper surface of the ceramic plate 51. As the brazing member 63, for example, silver brazing can be used.

### Configuration of Electrostatic Chuck 70

As shown in FIG. 1, the electrostatic chuck 70 includes a substrate body 71 and an electrode 72 embedded in the substrate body 71. The electrostatic chuck 70 is, for example, a Johnsen-Rahbek type electrostatic chuck. However, the electrostatic chuck 70 may be a Coulomb force type electrostatic chuck. The electrostatic chuck 70 is a holder that sucks and holds a substrate which is an object to be sucked.

The substrate body 71 is formed in a disk shape, for example. For example, a diameter of the substrate body 71 may be equal to the diameter of the upper portion 22 of the base plate 20 or may be larger than the diameter of the upper portion 22. The diameter of the substrate body 71 according to the present embodiment is equal to the diameter of the upper portion 22. The diameter of the substrate body 71 may be, for example, about 150 mm to 500 mm. A thickness of the substrate body 71 may be, for example, about 0.5 mm to 10 mm.

The substrate body 71 has a mounting surface 71A (here, an upper surface) on which a substrate as an object to be sucked is mounted. The substrate body 71 is, for example, a dielectric. The substrate body 71 is, for example, a ceramic substrate.

The substrate body 71 is provided with, for example, a gas flow path 73. The gas flow path 73 penetrates the substrate body 71 in the thickness direction. The gas flow path 73 is formed to open upward in the substrate body 71, and also to open downward in the substrate body 71. The gas flow path 73 communicates with the gas flow path 40 of the base plate 20. As shown in FIG. 2, the gas flow path 73 communicates with the hole portion 43 of the ceramic plate 52. The gas flow path 73 is formed to extend linearly along the thickness direction of the substrate body 71, for example. A planar size of the gas flow path 73 is, for example, smaller than the planar size of the hole portion 43, for example. That is, an opening area of the gas flow path 73 is smaller than the opening area of the hole portion 43. The gas flow path 73 as a whole is provided so as to overlap the hole portion 43 in a planar view. For example, the gas flow path 73 is provided at a position different from that of the hole portion 42 in a planar view.

As shown in FIG. 1, in the substrate fixing device 10, a gas hole 11 is formed by the gas flow path 40 and the gas flow path 73. The gas hole 11 penetrates from the mounting surface 71A of the substrate body 71 to the lower surface of the base plate 20 by the communication between the gas flow path 40 and the gas flow path 73. In the gas hole 11, the inert gas is introduced into the gas hole 11 through the gas flow path 40, and the inert gas is discharged from the gas hole 11 through the gas flow path 73. The inert gas discharged from the gas flow path 73 is, for example, filled between the lower surface of the substrate placed on the mounting surface 71A and the mounting surface 71A, so that the substrate can be cooled.

The electrode 72 is, for example, an electrostatic electrode for sucking a substrate placed on the mounting surface 71A. The electrode 72 is an electrode formed in a thin film shape. The electrode 72 is built in, for example, a portion of the substrate body 71 located near the mounting surface 71A in the thickness direction. For example, the electrode 72 is disposed on a plane parallel to the mounting surface 71A. The electrode 72 is electrically connected to, for example, a power supply for suction provided outside the substrate fixing device 10. When a predetermined voltage is applied from the power supply for suction, the electrode 72 generates an electrostatic suction force between the electrode 72 and the substrate placed on the mounting surface 71A. Accordingly, the substrate can be sucked and held on the mounting surface 71A. A suction holding force of the electrostatic chuck 70 increases as the voltage applied to the electrode 72 increases. The electrode 72 may have a unipolar shape or a bipolar shape. As a material of the electrode 72, for example, tungsten (W) or molybdenum (Mo) can be used. In each drawing, one electrode 72 is shown, but actually, a plurality of electrodes arranged on the same plane are included.

### Configuration of Brazing Part 80

As shown in FIG. 2, the brazing part 80 includes a conductive pattern 81 formed on the upper surface of the base plate 20, a conductive pattern 82 formed on the lower surface of the electrostatic chuck 70, and a brazing member 83 joining the conductive patterns 81 and 82.

The conductive pattern 81 is formed on the upper surface of the ceramic plate 52. For example, the conductive pattern 81 is provided so as to overlap the electrostatic chuck 70 in a planar view. For example, the conductive pattern 81 is provided so as not to overlap the hole portion 43 and the gas flow path 73 in a planar view. For example, the conductive pattern 81 covers the entire upper surface of the ceramic plate 52.

The conductive pattern 82 is formed on a lower surface of the substrate body 71. For example, the conductive pattern 82 is provided so as to overlap the conductive pattern 81 in a planar view. For example, the conductive pattern 82 is provided so as not to overlap the hole portion 43 and the gas flow path 73 in a planar view.

The brazing member 83 joins the conductive pattern 81 and the conductive pattern 82. The brazing member 83 is joined to the upper surface of the conductive pattern 81 and also joined to the lower surface of the conductive pattern 82. Thus, the conductive pattern 81 and the conductive pattern 82 are joined to each other by the brazing using the brazing member 83. The base plate 20 and the electrostatic chuck 70 are joined to each other by joining the conductive pattern 81 and the conductive pattern 82 to each other. Thus, the electrostatic chuck 70 is laminated on the upper surface of the base plate 20. As the brazing member 83, for example, silver brazing can be used.

### Configuration of Protective Layer 90

The protective layer 90 has a function of protecting the brazing parts 60 and 80 from plasma. The protective layer 90 is formed on an outer side surface of the base plate 20 and an outer side surface of the electrostatic chuck 70 so as to cover the brazing parts 60 and 80. The protective layer 90 covers the entire outer side surface of the brazing part 60. That is, the protective layer 90 covers the entire outer side surface of the conductive pattern 61, the entire outer side surface of the conductive pattern 62, and the entire outer side surface of the brazing member 63. The protective layer 90 covers the entire outer side surface of the brazing part 80. That is, the protective layer 90 covers the entire outer side surface of the conductive pattern 81, the entire outer side surface of the conductive pattern 82, and the entire outer side surface of the brazing member 83. The protective layer 90 covers the outer side surfaces of the brazing parts 60 and 80 over the entire circumference of the base plate 20. The protective layer 90 continuously covers the brazing part 60 and the brazing part 80, for example.

The protective layer 90 covers, for example, the entire outer side surface of the upper portion 22 of the base plate 20. That is, the protective layer 90 covers the entire outer side surface of the ceramic plate 52. The protective layer 90 covers, for example, a part of the outer side surface of the electrostatic chuck 70. The protective layer 90 covers, for example, a part of the outer side surface of the substrate body 71. The protective layer 90 of the present embodiment covers the outer side surface in the lower portion of the substrate body 71 and to expose the outer side surface in the upper portion of the substrate body 71.

As a material of the protective layer 90, for example, a low thermal expansion ceramic material can be used. Examples of the material of the protective layer 90 include ceramic materials such as aluminum oxide, aluminum nitride, and yttrium oxide. As the material of the protective layer 90, for example, a fluororesin or an epoxy resin having excellent plasma resistance may be used.

In the present embodiment, the gas flow path 40 is an example of a first gas flow path, the hole portion 41 is an example of a first hole portion, the hole portions 42 and 43 are examples of a second hole portion, and the gas flow path 73 is an example of a second gas flow path. The ceramic plate 51 is an example of a first ceramic plate, and the ceramic plate 52 is an example of a second ceramic plate. The brazing part 60 is an example of a second brazing part, the conductive pattern 61 is an example of a third conductive pattern, the conductive pattern 62 is an example of a fourth conductive pattern, and the brazing member 63 is an example of a second brazing member. The brazing part 80 is an example of a first brazing part, the conductive pattern 81 is an example of a first conductive pattern, the conductive pattern 82 is an example of a second conductive pattern, and the brazing member 83 is an example of a first brazing member.

### Manufacturing Method for Substrate Fixing Device 10

Next, a manufacturing method for the substrate fixing device 10 will be described. For convenience of description, the parts that become components of the substrate fixing device 10 will be described with reference numerals of the final components.

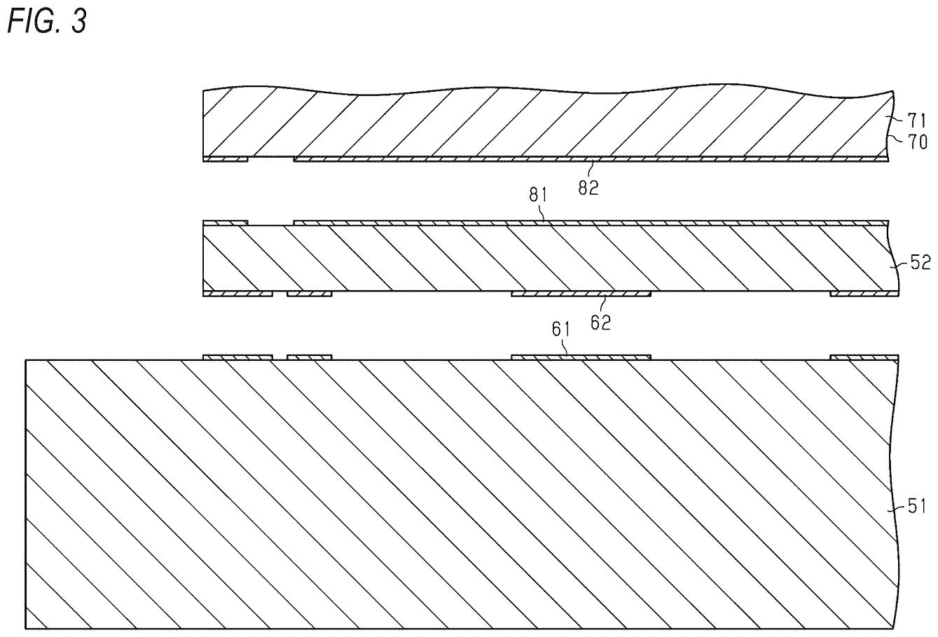

First, in a step shown in FIG. 3, the ceramic plate 51 whose upper surface is formed with the conductive pattern 61 for brazing is prepared. In addition, the ceramic plate 52 whose lower surface is formed with the conductive pattern 62 for brazing and whose upper surface is formed with the conductive pattern 81 for brazing is prepared. In addition, the electrostatic chuck 70 having the substrate body 71 whose lower surface is formed with the conductive pattern 82 for brazing is prepared. The two ceramic plates 51 and 52 and the substrate body 71 can be manufactured by, for example, a green sheet method.

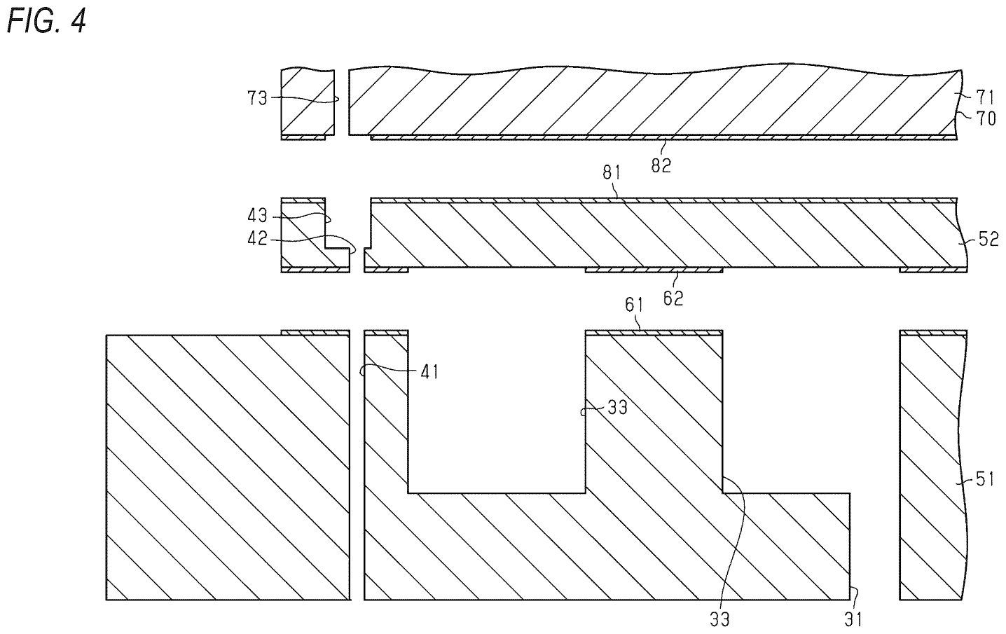

Subsequently, in a step shown in FIG. 4, the introduction portion 31, the discharge portion 32 (see FIG. 1), and the recessed portion 33 are formed in the ceramic plate 51, and the hole portion 41 is formed in the ceramic plate 51. The introduction portion 31, the discharge portion 32, the recessed portion 33, and the hole portion 41 can be formed by, for example, a laser processing method or a machining processing method.

In the step shown in FIG. 4, the hole portion 42 and the hole portion 43 are formed in the ceramic plate 52. The hole portion 42 and the hole portion 43 can be formed by, for example, a laser processing method or a machining processing method.

In the step shown in FIG. 4, the gas flow path 73 is formed in the substrate body 71. The gas flow path 73 can be formed by, for example, a laser processing method or a machining processing method.

Next, the ceramic plate 52 is disposed above the ceramic plate 51 in a state in which the conductive pattern 62 faces the conductive pattern 61. At this time, the ceramic plates 51 and 52 are aligned such that the hole portion 42 overlap the hole portion 41 in a planar view. The substrate body 71 is disposed above the ceramic plate 52 in a state in which the conductive pattern 82 faces the conductive pattern 81. At this time, the ceramic plate 52 and the substrate body 71 are aligned such that the gas flow path 73 overlaps the hole portion 43 in a planar view.

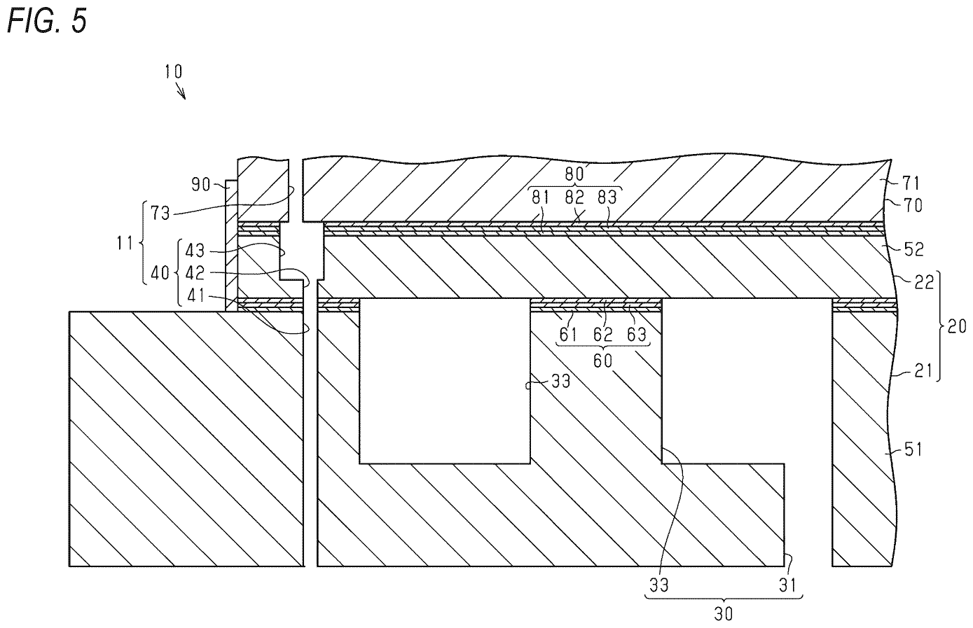

Next, in a step shown in FIG. 5, the conductive pattern 61 and the conductive pattern 62 are joined by the brazing using the brazing member 63. Accordingly, the ceramic plate 52 can be joined to the upper surface of the ceramic plate 51. Further, the conductive pattern 81 and the conductive pattern 82 are joined by the brazing using the brazing member 83. Accordingly, the substrate body 71 can be joined to the upper surface of the ceramic plate 52. According to this step, the opening of the recessed portion 33 is closed by the ceramic plate 52. As a result, the cooling path 30 is formed by the introduction portion 31, the discharge portion 32 (see FIG. 1), the recessed portion 33 formed in the ceramic plate 51, and the ceramic plate 52 that closes the opening of the recessed portion 33. Further, according to the present step, the gas flow path 40 is formed by communicating the hole portion 41 of the ceramic plate 51 with the hole portions 42 and 43 of the ceramic plate 52, and the gas flow path 40 communicates with the gas flow path 73 to form the gas hole 11.

According to the manufacturing steps described above, the base plate 20 having the ceramic plates 51 and 52 is formed, and the electrostatic chuck 70 is joined onto the base plate 20.

Next, the protective layer 90 that covers the brazing parts 60 and 80 is formed on the outer side surface of the ceramic plate 52 and the outer side surface of the substrate body 71. The protective layer 90 can be formed by, for example, a physical vapor deposition method or a chemical vapor deposition method. When a fluororesin or an epoxy resin is used as the material of the protective layer 90, for example, the protective layer 90 can be formed by applying a liquid resin to the outer side surface of the ceramic plate 52 and the outer side surface of the substrate body 71 and then curing the resin.

According to the above manufacturing steps, the substrate fixing device 10 according to the present embodiment can be manufactured.

Next, the operation and effect of the present embodiment will be described.

(1) The substrate fixing device 10 includes the ceramic base plate 20, the ceramic electrostatic chuck 70 having the mounting surface 71A on which an object to be sucked is mounted, and the brazing part 80 joining the base plate 20 and the electrostatic chuck 70. The base plate 20 is made of a ceramic material having a thermal expansion coefficient of 0±5 ppm/K at the room temperature. The electrostatic chuck 70 is made of a ceramic material having a thermal expansion coefficient of 0±5 ppm/K at the room temperature.

According to this configuration, the base plate 20 and the electrostatic chuck 70 are both made of a low thermal expansion ceramic material. Therefore, even when the substrate fixing device 10 is exposed to a low temperature of about −60° C. or a high temperature of about 180° C., thermal deformation, such as thermal expansion or thermal contraction, hardly occurs in the base plate 20 and the electrostatic chuck 70. Accordingly, even when the substrate fixing device 10 is exposed to a low temperature of about −60° C. or a high temperature of about 180° C., it is possible to suitably reduce a large difference between a thermal deformation amount of the base plate 20 and a thermal deformation amount of the electrostatic chuck 70. As a result, it is possible to suitably prevent thermal stress caused by thermal expansion and thermal contraction from acting on the brazing part 80 provided between the base plate 20 and the electrostatic chuck 70. As a result, it is possible to suitably prevent the brazing part 80 from being broken due to the thermal stress. Therefore, it is possible to suitably prevent the decrease in in-plane uniformity of the thermal resistance of the brazing part 80 due to the breakdown of the brazing part 80. As a result, variation in the temperature of the mounting surface 71A of the electrostatic chuck 70 can be prevented, and uniformity of the temperature of the mounting surface 71A of the electrostatic chuck 70 can be improved.

(2) During an operation of the substrate fixing device 10, the temperature of the base plate 20 and the temperature of the electrostatic chuck 70 may be different from each other. At this time, even when the base plate 20 and the electrostatic chuck 70 are made of the same ceramic material, when the thermal expansion coefficient of the ceramic material is 6 ppm/K to 8 ppm/K, the thermal stress is generated due to a difference in thermal expansion due to the temperature difference.

On the other hand, in the substrate fixing device 10 according to the present embodiment, the base plate 20 and the electrostatic chuck 70 are both made of a low thermal expansion ceramic material. Therefore, even when the temperature of the base plate 20 and the temperature of the electrostatic chuck 70 are different from each other, the thermal deformation hardly occurs in the base plate 20 and the electrostatic chuck 70. Accordingly, it is possible to suitably reduce a large difference between the thermal deformation amount of the base plate 20 and the thermal deformation amount of the electrostatic chuck 70. As a result, it is possible to suitably prevent the thermal stress caused by the thermal expansion and the thermal contraction from acting on the brazing part 80 that joins the base plate 20 and the electrostatic chuck 70.

(3) Even when the substrate fixing device 10 is exposed to a low temperature of about −60° C. or a high temperature of about 180° C., it is possible to prevent the substrate fixing device 10 (that is, the base plate 20, the electrostatic chuck 70, and the brazing part 80) from being damaged. Therefore, the single substrate fixing device 10 can be suitably used in a wide temperature range.

(4) In the substrate fixing device 10, the base plate 20 is more preferably made of a ceramic material having a thermal expansion coefficient of 0±1 ppm/K at the room temperature. The electrostatic chuck 70 is more preferably made of a ceramic material having a thermal expansion coefficient of 0±1 ppm/K at the room temperature. Accordingly, even when the temperature of the base plate 20 and the temperature of the electrostatic chuck 70 are different from each other, the occurrence of thermal deformation in the base plate 20 and the electrostatic chuck 70 is further prevented. Therefore, the difference between the thermal deformation amount of the base plate 20 and the thermal deformation amount of the electrostatic chuck 70 can be further suitably prevented. As a result, it is possible to more suitably prevent the thermal stress caused by thermal expansion and the thermal contraction from acting on the brazing part 80 that joins the base plate 20 and the electrostatic chuck 70.

(5) The protective layer 90 is formed on the outer side surface of the base plate 20 and the outer side surface of the electrostatic chuck 70 so as to cover the brazing parts 60 and 80. The protective layer 90 can protect the brazing parts 60 and 80 from plasma. As a result, it is possible to prevent the brazing parts 60 and 80 from being deteriorated by plasma, so that the lifetime of the substrate fixing device 10 can be prolonged.

(6) The brazing part 80 includes the conductive pattern 81 formed on the upper surface of the base plate 20, the conductive pattern 82 formed on the lower surface of the electrostatic chuck 70, and the brazing member 83. In this configuration, the electrostatic chuck 70 is joined onto the base plate 20 by joining the conductive patterns 81 and 82 by the brazing using the brazing member 83. The substrate fixing device 10 thus formed has a structure having the conductive patterns 81 and 82. Therefore, the rigidity of the substrate fixing device 10 can be increased, for example, as compared with a case where the base plate 20 and the electrostatic chuck 70 are joined to each other by an adhesive.

(7) The base plate 20 is constituted by the plurality of ceramic plates 51 and 52 joined to each other by the brazing part 60. In this configuration, the conductive patterns 61 and 62 are provided for the ceramic plates 51 and 52. Then, the conductive patterns 61 and 62 are joined by brazing with the brazing member 63, whereby the ceramic plate 52 is joined onto the ceramic plate 51. The base plate 20 thus formed has a structure having the conductive patterns 61 and 62. Therefore, the rigidity of the base plate 20 can be increased, for example, as compared with a case where the ceramic plates 51 and 52 are joined to each other by an adhesive.

(8) The plurality of ceramic plates 51 and 52 are joined to the brazing part 60, and the base plate 20 and the electrostatic chuck 70 are joined to the brazing part 80. According to this configuration, the ceramic plates 51 and 52 and the substrate body 71 can be joined to each other by the brazing members 63 and 83 that are harder than the adhesive. This can improve airtightness of the cooling path 30 formed in the ceramic plates 51 and 52 and the gas hole 11 formed in the substrate body 71.

### OTHER EMBODIMENTS

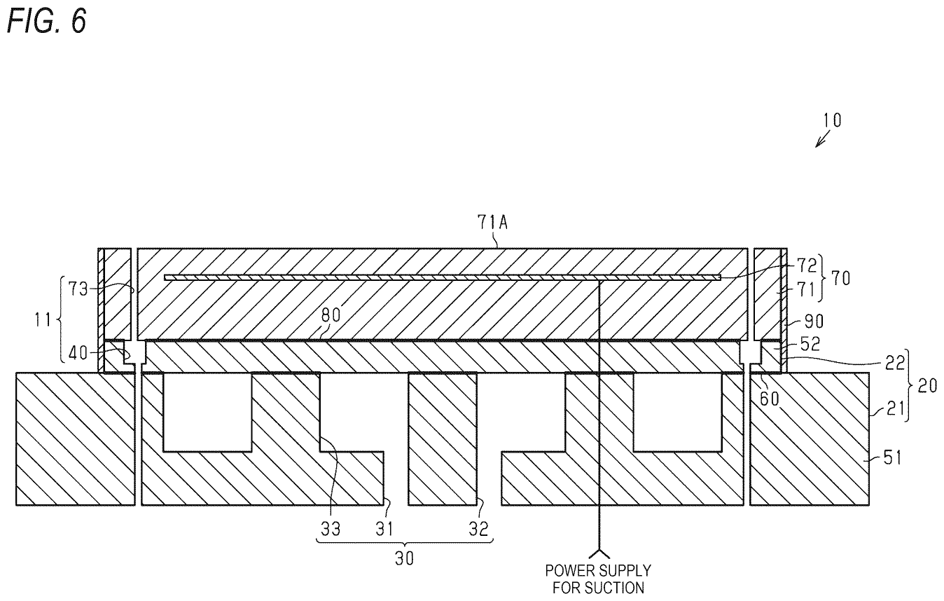

The above embodiment can be modified as follows. The above embodiment and the following modification can be combined with each other within a technical contradiction.
The structure of the substrate fixing device 10 according to the above embodiment can be appropriately changed.
For example, as shown in FIG. 6, the protective layer 90 may be formed so as to cover the entire outer side surface of the upper portion 22 of the base plate 20 and to cover the entire outer side surface of the electrostatic chuck 70. That is, the protective layer 90 may be formed so as to cover the entire outer side surface of the ceramic plate 52 and the entire outer side surface of the substrate body 71.
In the modification shown in FIG. 6, the protective layer 90 may cover the entire outer side surface of the lower portion 21 of the base plate 20. That is, the protective layer 90 may cover the entire outer side surface of the ceramic plate 51.
The protective layer 90 according to the above embodiment may be omitted.
The electrostatic chuck 70 according to the above embodiment may include an electrode different from the electrode 72. Examples of the other electrode include a heating element for heating the substrate placed on the mounting surface 71A.
An embossing may be provided on the mounting surface 71A of the electrostatic chuck 70 according to the above embodiment.
A shape of the gas hole 11 in the substrate fixing device 10 according to the above embodiment may be appropriately changed. The gas hole 11 may be omitted.
A shape of the cooling path 30 in the base plate 20 according to the above embodiment may be appropriately changed. The cooling path 30 may be omitted.
In the above embodiment, the base plate 20 and the electrostatic chuck 70 are joined to each other by the brazing part 80, but the present invention is not limited thereto. For example, the base plate 20 and the electrostatic chuck 70 may be joined together by joining the conductive patterns 81 and 82 to each other by a conductive adhesive.
In the base plate 20 according to the above embodiment, the ceramic plates 51 and 52 are joined to each other by the brazing part 60, but the present invention is not limited thereto. For example, the conductive patterns 61 and 62 may be joined to each other by a conductive adhesive. The conductive patterns 61 and 62 may be omitted, and the ceramic plates 51 and 52 may be joined to each other by an adhesive such as a silicone adhesive.
The number of the ceramic plates 51 and 52 in the base plate 20 according to the above embodiment is not particularly limited. For example, the number of ceramic plates included in the base plate 20 may be one, or three or more.
In the manufacturing method according to the above embodiment, the recessed portion 33 and the hole portions 41, 42, and 43 are formed on the ceramic plates 51 and 52 after the green sheet is fired, but the present invention is not limited thereto. For example, the recessed portion 33 and the hole portions 41, 42, and 43 may be formed on the green sheet before the green sheet is fired, that is, on the green sheet before firing.
In the manufacturing method according to the above embodiment, the gas flow path 73 is formed on the substrate body 71 after the green sheet is fired, but the present invention is not limited thereto. For example, the gas flow path 73 may be formed on the green sheet before the green sheet is fired, that is, on the green sheet before firing.
The substrate fixing device 10 according to the above embodiment is applied to a semiconductor manufacturing device, for example, a dry etching device. Examples of the dry etching device include a parallel plate type reactive ion etching device. The substrate fixing device 10 can also be applied to a semiconductor manufacturing device such as a plasma chemical vapor deposition (CVD) device or a sputtering device.

What is claimed is:

1. A substrate fixing device comprising:
a ceramic base plate;
a ceramic electrostatic chuck having a mounting surface on which an object to be sucked is mounted; and
a first brazing part joining the base plate and the electrostatic chuck, wherein
the base plate is made of a ceramic material having a thermal expansion coefficient of 0±3 ppm/K at a room temperature, and
the electrostatic chuck is made of a ceramic material having a thermal expansion coefficient of 0±3 ppm/K at the room temperature.

2. The substrate fixing device according to claim 1, wherein
the base plate is made of a ceramic material having a thermal expansion coefficient of 0±1 ppm/K at the room temperature, and
the electrostatic chuck is made of a ceramic material having a thermal expansion coefficient of 0±1 ppm/K at the room temperature.

3. The substrate fixing device according to claim 1, further comprising:
a protective layer formed on an outer side surface of the base plate and an outer side surface of the electrostatic chuck so as to cover the first brazing part.

4. The substrate fixing device according to claim 3, wherein
the base plate has a lower portion and an upper portion laminated on an upper surface of the lower portion,
a planar size of the upper portion is formed smaller than a planar size of the lower portion, and
the protective layer is formed so as to cover an entire outer side surface of the upper portion and to cover an entire outer side surface of the electrostatic chuck.

5. The substrate fixing device according to claim 1, wherein
the first brazing part includes
a first conductive pattern formed on an upper surface of the base plate,
a second conductive pattern formed on a lower surface of the electrostatic chuck, and
a first brazing member joining the first conductive pattern and the second conductive pattern.

6. The substrate fixing device according to claim 1, wherein
the base plate includes
a first ceramic plate,
a second ceramic plate provided on the first ceramic plate, and
a second brazing part joining the first ceramic plate and the second ceramic plate, and
the second brazing part includes
a third conductive pattern formed on an upper surface of the first ceramic plate,
a fourth conductive pattern formed on a lower surface of the second ceramic plate, and
a second brazing member joining the third conductive pattern and the fourth conductive pattern.

7. The substrate fixing device according to claim 6, wherein
the base plate has a cooling path formed by a recessed portion recessed downward from the upper surface of the first ceramic plate and the second ceramic plate provided so as to close an opening of the recessed portion,
the third conductive pattern is provided so as to overlap the second ceramic plate in a planar view, and
the fourth conductive pattern is provided so as to overlap the third conductive pattern, but not to overlap the recessed portion, in a planar view.

8. The substrate fixing device according to claim 6, wherein
the base plate has a first gas flow path which penetrates the base plate in a thickness direction,
the electrostatic chuck has a second gas flow path which communicates with the first gas flow path,
the first gas flow path has a first hole portion which penetrates the first ceramic plate in the thickness direction, and a second hole portion which penetrates the second ceramic plate in the thickness direction and communicates with the first hole portion, and
the second gas flow path is formed so as to penetrate the electrostatic chuck in the thickness direction and to communicate with the second hole portion.

9. The substrate fixing device according to claim 1, further comprising:
an electrode built in the electrostatic chuck.

10. The substrate fixing device according to claim 1, wherein
the base plate and the electrostatic chuck are made of a ceramic material having the same material as a main component.
